(19) United States
(12) Patent Application Publication
(10) Pub. No.: US 2011/0129982 A1
(43) Pub. Date: Jun. 2, 2011

(54) Method for Forming a Capacitor of a Semiconductor Memory Device

(75) Inventor: Jong Bum Park, Seoul (KR)

(73) Assignee: HYNIX SEMICONDUCTOR INC, Icheon-si (KR)

(21) Appl. No.: 13/007,269

(22) Filed: Jan. 14, 2011

Related U.S. Application Data
(62) Division of application No. 12/341,822, filed on Dec. 22, 2008.

(30) Foreign Application Priority Data
May 21, 2008 (KR) 10-2008-0047007

(51) Int. Cl. H01L 21/20

(52) U.S. Cl. 438/397; 257/E21.09

(57) ABSTRACT

A semiconductor device that is capable of preventing a storage node bunker defect or a defect due to loss of a barrier layer, and a method for forming a capacitor thereof. The semiconductor memory device includes a contact hole formed in an interlayer dielectric layer on a semiconductor substrate; a barrier layer formed on the bottom of the contact hole; a first storage node contact formed of a conductive layer that fills the rest of the contact hole; a second storage node contact formed on the result formed with the first storage node contact so as to be shifted by a given distance from the first storage node contact; an insulation layer formed between the second storage node contacts; a storage electrode connected with the second storage node contact and isolated on a per cell basis; and dielectric layer and plate electrode for covering the storage electrode.

### CROSS-REFERENCE TO RELATED APPLICATION

This is a division of U.S. application Ser. No. 12/341,822 filed Dec. 22, 2008, which claims the priority benefit under USC 119 of KR 10-2008-0047007 filed May 21, 2008, the entire respective disclosures of which are incorporated herein by reference.

### BACKGROUND OF THE INVENTION

The invention relates to a semiconductor device and a method for fabricating the same and, more particularly, to a semiconductor memory device provided with a cylindrical storage electrode and a method for forming a capacitor of the semiconductor memory device.

Due to high degree of integration and a resultant decrease in design rule of semiconductor devices, it is difficult to realize the memory devices within a limited area. For example, in the case of DRAM devices that are constituted of unit memory cells respectively including one transistor and one capacitor, it becomes more difficult to realize the capacitor having sufficient capacitance within a limited area. In order to obtain sufficient capacitance within a limited area, it may be desired to increase an effective surface area of a storage electrode. In one solution, it may be preferred to increase the height of the storage electrode. Particularly, in the case of a cylindrical storage electrode, the electrode height has increased to increase the effective surface area while the electrode diameter has decreased. Therefore, an aspect ratio of the cylindrical storage electrode has increased to a great degree.

As a result, step coverage properties of the dielectric layer of the capacitor have deteriorated and capacitance has decreased, consequently resulting in reduction in yield.

FIGS. 1 to 3 are cross-sectional views illustrating a conventional method for forming a capacitor provided with a cylindrical storage electrode.

Referring to FIG. 1, first and second storage node contacts 110 and 130 are formed in interlayer dielectric layers 100 and 120 formed on a semiconductor substrate (not shown). The second storage node contact 130 is formed by forming a contact hole by etching the interlayer dielectric layer 120 so that the first storage node contact 110 is exposed, a polysilicon layer doped with impurities is filled in the contact hole, and then the doped polysilicon layer is etched back. An etch stop layer 140 and a sacrificial layer 150 are sequentially formed on the result formed with the second storage node contact 130. An opening for exposing the second storage node contact 130 is formed by sequentially anisotropically etching the sacrificial layer 150 and the etch stop layer 140.

Referring to FIG. 2, a barrier layer 160 for lowering contact resistance between a storage electrode and the second storage node contact 130 is formed by forming titanium silicide (TiSi₂) on the bottom of the opening. After that, on the entire surface of the result formed with the barrier layer 160, for example, titanium nitride (TiN) is deposited with a predetermined thickness and then subjected to an etch back process or a chemical mechanical polishing (CMP) process, for example, thereby forming a storage electrode 170 isolated on a per cell basis.

Referring to FIG. 3, the storage electrode 170 is separated in a unit cell basis by dipping out the sacrificial layer (150 in FIG. 2) using an oxide layer etchant. A dielectric layer 180 is formed by depositing dielectric material on this result and then a plate electrode 190 is formed by depositing a conductive layer over an entire surface of the dielectric layer 180.

Meanwhile, in the situation wherein spacing between cylinders becomes narrower and the height of the cylinder becomes higher due to high integration and decrease in design rule of semiconductor devices, decreasing the thickness of the titanium nitride (TiN) for the storage electrode improves the step coverage of the dielectric layer and increase an internal area of the cylinder, resulting in increase in the cell capacitance.

However, decreasing the thickness of the conductive layer for the storage electrode may cause a problem that the wet etchant penetrates into the conductive layer 170 for the storage electrode during a full dip out process for removing the sacrificial layer using the wet etchant and thus a storage node bunker defect is generated or the barrier layer 160 placed between the storage electrode and the second storage node contact is lost. This phenomenon is generated variously depending on the penetration degree of the etchant to the conductive layer for the storage electrode. When the penetration degree is low, a single-bit failure due to the loss of the barrier layer 160 is generated. On the contrary, when the degree of penetration degree, a multi-bit failure due to not only the loss of the barrier layer 160 but also the storage bunker is generated, which has an adverse influence on the device.

The storage bunker is generated as the etchant penetrates into the conductive layer for the storage electrode and thus etches the interlayer dielectric layer 140, and a disconnection is caused between a metal wiring layer and the storage node contact by penetration of conductive material into the bunker during the follow-up processes. Also, a faulty pattern is caused during the photolithography process for forming the metal wiring layer, which may be a cause of the reduction in the yield. Further, in the conventional cylinder, the storage electrodes are in contact with each other and thus a bridge is generated, resulting in the multi-bit fail.

### SUMMARY OF THE INVENTION

The invention provides a semiconductor device that is capable of preventing a storage node bunker defect or a defect due to lost of a barrier layer, and a method for forming a capacitor thereof.

In one embodiment, the invention provides a semiconductor memory device, comprising:
a plurality of contact holes each having a bottom and formed in an interlayer dielectric layer on a semiconductor substrate;
a barrier layer formed on the bottom of each contact hole;
a plurality of first storage node contacts each comprising a conductive layer filling the contact holes;
a plurality of second storage node contacts formed over, connected to, and shifted a predetermined distance from the first storage node contacts;
an insulation layer formed between the second storage node contacts;
storage electrodes connected to the second storage node contacts and isolated on a unit cell basis; and
a dielectric layer and plate electrodes for covering the storage electrodes.

In another embodiment, the invention provides a method for forming a capacitor of a semiconductor memory device, comprising:
(a) forming a first contact hole having a bottom in a first interlayer dielectric layer formed on a semiconductor substrate;
(b) forming a barrier layer on the bottom of the first contact hole;
(c) forming a first storage node contact filling the first contact hole;
(d) forming a second interlayer dielectric layer on the result of (c) on which the first storage node contact is formed;
(e) forming a second contact hole for exposing a portion of the first storage node contact;
(f) forming a second storage node contact by filling the second contact hole with a conductive layer;
(g) forming a sacrificial layer on the result of (f) in which the second storage node contact is formed;
(h) etching the sacrificial layer to expose the second storage node contact;
(i) forming a cylindrical storage electrode isolated on a unit cell basis on the result of (i) on which the sacrificial layer is etched;
(j) removing the sacrificial layer by a dip out process; and
(k) forming a dielectric layer and a plate electrode to cover the storage electrode.

In another embodiment, the invention provides a method for forming a capacitor of a semiconductor memory device, comprising:
(a) forming a first contact hole in a first interlayer dielectric layer formed on a semiconductor substrate;
(b) forming a first storage node contact by filling the first contact hole with a conductive layer;
(c) forming a second interlayer dielectric layer on the result of (b) formed on the first storage node contact;
(d) forming a second storage hole in the second interlayer dielectric layer to expose a portion of the first storage node contact;
(e) forming a second storage node contact by filling the second contact hole with a conductive layer;
(f) removing the second interlayer dielectric layer;
(g) forming an etch stop layer on the result of (f) from which the second interlayer dielectric layer is removed;
(h) forming a sacrificial layer on the etch stop layer;
(i) patterning the sacrificial layer and the etch stop layer to expose the second storage node contact;
(j) forming a storage electrode isolated on a unit cell basis;
(k) removing the sacrificial layer by a dip out process; and
(l) forming a dielectric layer and a plate electrode covering the storage electrode.

### BRIEF DESCRIPTION OF THE DRAWINGS

FIGS. 1 to 3 are cross-sectional views illustrating a conventional method for forming a capacitor provided with a cylindrical storage electrode.

FIG. 4 is a cross-sectional view illustrating a capacitor of a semiconductor memory device in accordance with an embodiment of the invention.

FIGS. 5 to 10 are cross-sectional views illustrating a method for forming the capacitor of the semiconductor memory device in accordance with an embodiment of the invention.

FIG. 11 is a cross-sectional view illustrating a method for forming a capacitor of a semiconductor memory device in accordance with another embodiment of the invention.

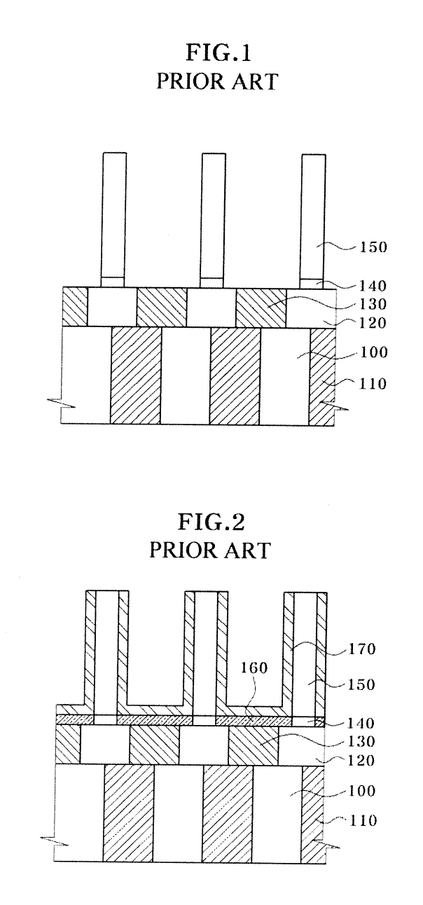

### DESCRIPTION OF SPECIFIC EMBODIMENTS

Hereinafter, a method for fabricating a photomask in accordance with the invention will be described in detail with reference to the accompanying drawings.

FIG. 4 is a cross-sectional view illustrating a capacitor of a semiconductor memory device in accordance with an embodiment of the invention. For simplification of description, structures under the capacitor such as a transistor, a bit line, and a landing plug contact formed on the semiconductor substrate are not shown.

Referring to FIG. 4, the semiconductor memory device in accordance with an embodiment of the invention includes a contact hole formed in an interlayer dielectric layer 210 on a semiconductor substrate 200, a barrier layer 220 formed on the bottom of the contact hole, a first storage node contact 230 that fills the rest of the contact hole, a second storage node contact 250 connected to the first storage node contact 230, an insulation layer 260 formed between the second storage node contacts 250 to isolate the second storage node contacts 250 from each other, a cylindrical storage electrode 280 connected to the second storage node contact 250 and isolated on a unit cell basis, a dielectric layer 290 surrounding the storage electrode 280, and a plate electrode 300.

The barrier layer 220 prevents reaction between a conductive region of the semiconductor substrate 200 or the landing plug contact formed on the semiconductor substrate and the first storage node contact 230, thus reducing resistance of the storage node contact. The barrier layer 220 is preferably formed of, for example, metal silicide. Examples of metal for the metal silicide include titanium (Ti), tungsten (W), and cobalt (Co).

The first storage node contact 230 and the second storage node contact 250 are preferably formed of metal, metal nitride, or metal oxide. The second storage node contact 250 intermediately connects the storage electrode 280 and the first storage node contact 230 and is preferably arranged so as to be shifted by a predetermined distance from the first storage node contact 230. Preferred examples of material for the first and second storage node contacts include titanium nitride (TiN), tantalum nitride (TaN), hafnium nitride (HfN), tungsten (W), ruthenium (Ru), ruthenium oxide (RuO₂), platinum (Pt), iridium (Ir), and iridium oxide (IrO).

The insulation layer 260 electrically isolates the second storage node contacts 250 by being disposed between the second storage node contacts 250. The insulation layer 260 is preferably formed of an oxide layer (SiOₓ) or a nitride layer (SiN). When the insulation layer 260 is formed of the oxide layer, penetration of an etchant during a process of dipping out a sacrificial layer for forming the cylinder is prevented. Also, the height of the insulation layer 260 is preferably, as shown, higher than or equal to that of the second storage node contact 250. When the insulation layer 260 is higher than the second storage node contact 250, it can support the lower portion of the storage electrode to prevent falling down of the storage electrode. In this case, it is preferred that the insulation layer 260 is 300 Å to 500 Å higher than the second storage node contact 250.

The storage electrode 280 is preferably formed of titanium nitride (TiN), tantalum nitride (TaN), hafnium nitride (HfN), ruthenium (Ru), ruthenium oxide (RuO₂), platinum (Pt), iridium (Ir), or iridium oxide (IrO). The thinner the storage electrode 280 is, the better the step coverage is upon subsequent deposition of the dielectric layer, and the interior area of the cylinder is increased. However, when the storage electrode 280 is too thin, the etchant can readily penetrate during the process of dipping out the sacrificial layer and thus the storage electrode may collapse. Therefore, it is preferred that the thickness of the storage electrode is 100 Å to 500 Å.

In accordance with the semiconductor memory device as described above, since the first and second storage node contacts 230 and 250 are preferably formed of metal, metal oxide, or metal nitride, it is possible to reduce the contact resistance as compared to that of a polysilicon storage node contact. Also, since the barrier layer 260 is disposed below the first storage node contact 230, the problem of loss of the barrier layer is avoided even if the oxide etchant penetrates into the second storage node contact 250 through the storage electrode 280 when removing the sacrificial layer by a dip out process. Further, since a nitride layer 260 is disposed between the second storage node contacts 250, it is not readily etched by the oxide layer etchant and thus a bunker defect is avoided.

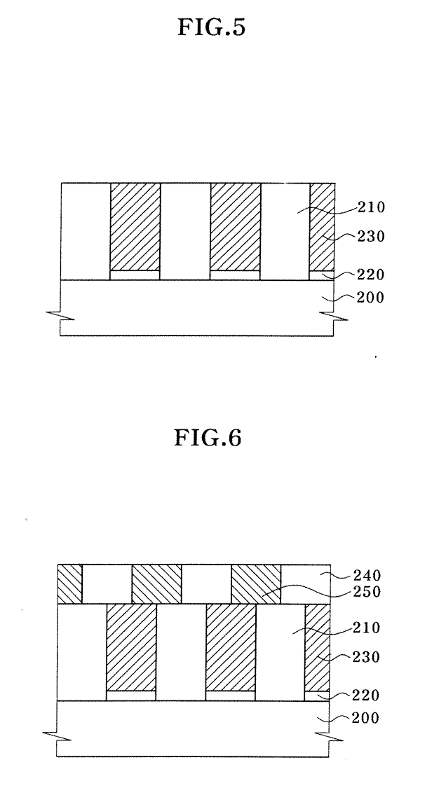

FIGS. 5 to 10 are cross-sectional views illustrating a method for forming the capacitor of the semiconductor memory device in accordance with an embodiment of the invention.

Referring to FIG. 5, a contact hole is formed by etching a first interlayer dielectric layer 210 formed on a semiconductor substrate 200. Though not shown, under structures such as a transistor, a bit line and a landing plug contact are formed over the semiconductor substrate 200. On the bottom of the contact hole, a barrier layer 220 for preventing reaction between the a first storage node contact and the semiconductor substrate 200 or the first storage node contact and the landing plug contact (not shown) formed on the semiconductor substrate is formed.

The barrier layer 220 is preferably formed of metal silicide. To this end, a metal layer, for example, a titanium (Ti) layer, is deposited, preferably in a thickness of 20 Å to 100 Å. Next, a rapid thermal annealing (RTA) or equivalent process is performed on the deposited Ti layer and then a barrier layer of titanium silicide (TiSi₂) is preferably formed by reaction between the titanium and silicon of the semiconductor substrate 200. The RTA process is preferably performed at a temperature of 700° C. to 900° C. under an atmosphere of nitrogen gas (N₂) for 10 seconds to 300 seconds. Besides titanium (Ti), tungsten (W) or cobalt (Co) are suitably used as the metal for forming the barrier layer 220.

On the result formed with the barrier layer 220, a conductive layer is deposited in a thickness of 200 Å to 1,000 Å. The first storage node contact 230 for filling the contact hole is formed, preferably by performing an etch back or Chemical Mechanical Polishing (CMP) process on the conductive layer. The first storage node contact 230 is preferably formed of one of titanium nitride (TiN), tantalum nitride (TaN), hafnium nitride (HfN), tungsten (W), ruthenium (Ru), ruthenium oxide (RuO₂), platinum (Pt), iridium (Ir), and iridium oxide (IrO). The process of forming the barrier layer may be omitted when the first storage node contact 230 is formed of a polysilicon layer.

Referring to FIG. 6, on the result formed with the first storage node contact 230, a second interlayer dielectric layer 240 is formed, preferably by depositing e.g. an oxide layer. By anisotropically etching the second interlayer dielectric layer 240, a contact hole for exposing the first storage node contact 230 is formed. The contact hole is formed so as to be shifted by a predetermined distance from the first storage node contact 230, thereby exposing some portion of the first storage node contact 230.

To fill the contact hole, a conductive layer, for example, titanium nitride (TiN) is deposited, preferably in a thickness of 200 Å to 1,000 Å. The second storage node contact 250 is formed, preferably by performing an etch back or CMP process on the conductive layer.

The second storage node contact 250 is preferably formed of one of titanium nitride (TiN), tantalum nitride (TaN), hafnium nitride (HfN), tungsten (W), ruthenium (Ru), ruthenium oxide (RuO₂), platinum (Pt), iridium (Ir), and iridium oxide (IrO). When the second storage node contact 250 is formed of a polysilicon layer, a barrier layer for preventing reaction between the second storage node contact 250 and the storage electrode to be formed in the follow-up step may be formed on the second storage node contact 250. This barrier layer is preferably formed in the same manner as the barrier layer 220 formed below the first storage node contact 230.

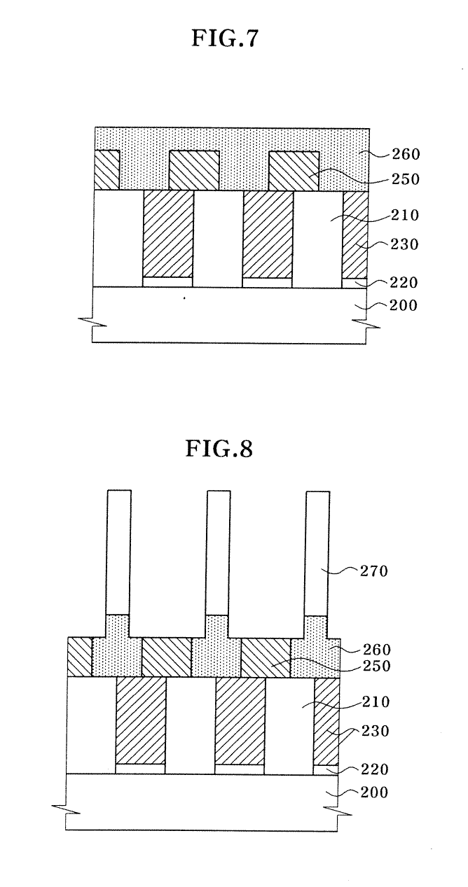

Referring to FIG. 7, the second interlayer dielectric layer is removed to prevent that oxide etchant comes in contact with the second interlayer dielectric layer (240 in FIG. 5) through the conductive layer for the storage electrode during a subsequent dip out process for the sacrificial layer. In the case wherein the second interlayer dielectric layer is formed of an oxide layer, the second interlayer dielectric layer is preferably removed using buffered oxide etchant (BOE) or diluted hydrofluoric acid (HF) solution.

After the second interlayer dielectric layer is removed, an etch stop layer 260 is formed on the entire surface of the result. The etch stop layer 260 is formed as an insulation layer having an etch selectivity ratio to the sacrificial layer for forming the storage electrode. It is preferred that the etch stop layer 260 is formed of a silicon nitride layer when the sacrificial layer is formed of an oxide layer. The etch stop layer 260 is preferably formed using a low pressure chemical vapor deposition (LP-CVD) or a plasma enhanced chemical vapor deposition (PE-CVD). The etch stop layer 260 is preferably formed in a thickness of 300 Å to 1,000 Å so that the second storage node 250 is not exposed.

An etch back process or a CMP process is preferably performed on the etch stop layer 260 to expose the second storage node contact 250 as shown in FIG. 250.

Referring to FIG. 8, on the result formed with the etch stop layer 260, the sacrificial layer 270 for forming a cylindrical electrode is formed, preferably by depositing an oxide layer in a predetermined thickness, for example, 1,000 Å to 30,000 Å. The thickness of the sacrificial layer 270 is determined by the height of the storage electrode to be formed.

As the sacrificial layer 270, an oxide layer such as phosphor-silicated glass (PSG) or PE-TEOS is preferably formed in a single layer or multi-layer. When the sacrificial layer is formed in multi-layer, a thickness ratio of respective layers may be controlled if necessary.

On the sacrificial layer 270, a photoresist pattern (not shown) for defining a region to be formed with the storage electrode is formed. By etching the sacrificial layer 270 and the etch stop layer 260 using the photoresist pattern as an etching mask, the second storage node contact 250 is exposed, and then the photoresist pattern is removed. The etching on the etch stop layer 260 is performed until the second storage node contact 250 is exposed. When an etch back process or CMP is performed to expose the second storage node contact after forming the etch stop layer 260, the etching on the etch stop can be omitted.

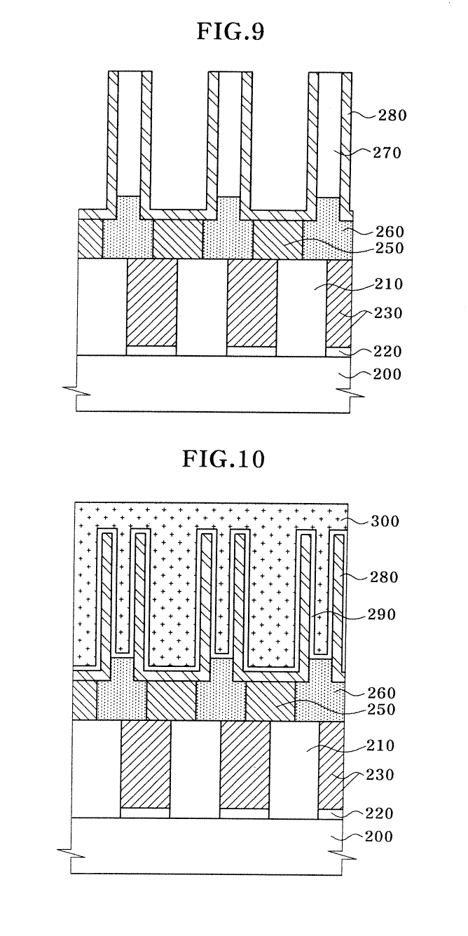

Referring to FIG. 9, on the result on which the sacrificial layer and the etch stop layer are patterned, a conductive layer for a storage electrode is deposited. The conductive layer for the storage electrode is preferably formed using metal, metal oxide or metal nitride such as titanium nitride (TiN), tantalum nitride (TaN), hafnium nitride (HfN), ruthenium (Ru), ruthenium oxide (RuO₂), platinum (Pt), iridium (Ir), or iridium oxide (IrO). Also, to increase a capacitance and enhance the leakage current properties through increase in an area of a cylinder hole and improvement of step coverage properties of the dielectric layer, it is preferred that the conductive layer for the storage electrode is formed in a thickness of 100 Å to 500 Å.

Next, an etch back or CMP process is preferably performed on the deposited conductive layer for the storage electrode, thereby forming a storage electrode 280 isolated on a unit cell basis. After forming the storage electrode, heat treatment may be performed in a furnace to improve the quality of the storage electrode. This heat treatment is preferably performed at a temperature of 550 to 650° C. under an atmosphere of nitrogen gas (N₂) for 10 minutes to 30 minutes.

Referring to FIG. 10, the sacrificial layer (270 in FIG. 8) remaining within the cylinder is removed, preferably using an oxide etchant such as BOE, thereby completing the cylindrical storage electrode 280. At this time, when removing not only the sacrificial layer within the cylinder but also the sacrificial layer between the cylinders, it is possible to increase the capacitance since it is possible to use both the inside and outside of the cylinder as the effective capacitor area. Next, a dielectric layer 290 and a plate electrode 300 are formed by sequentially depositing a dielectric layer and conductive layer on the result.

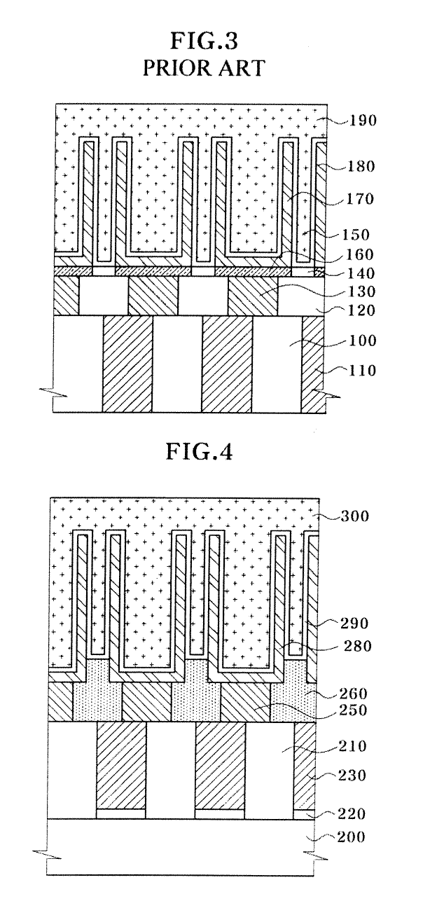

The step of removing the sacrificial layer is preferably performed in a wet etching manner using an oxide etchant. In this procedure, the etchant may penetrate into the thin storage electrode 280. In conventional practice, since the second storage node contact (130 in FIG. 3) is formed of a polysilicon layer, a barrier layer (160 in FIG. 3) is formed on the upper portion of the second storage node contact to prevent the reaction between the second storage node contact and the storage electrode (170 in FIG. 3). Therefore, there is a problem that the barrier layer (160 in FIG. 3) is lost when the oxide etchant penetrates into the thin storage electrode. Also, since the second interlayer dielectric layer (120 in FIG. 3) is formed of an oxide layer, a bunker defect may occur when the etchant penetrates into the second interlayer dielectric layer (120 in FIG. 3), which has a fatal influence on a semiconductor device.

However, in the invention, since the path through which the etchant reaches to the barrier layer through the storage electrode layer becomes long by forming the first and second storage node contacts 230 and 250, preferably with metal, metal oxide, or metal nitride, the problem of loss of the barrier layer does not occur.

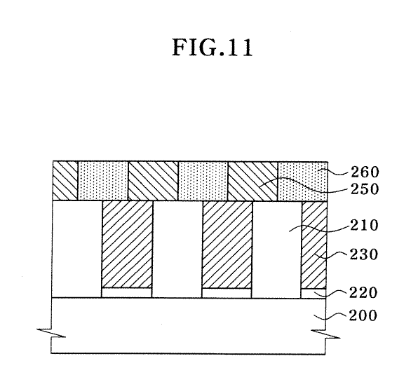

FIG. 11 is a cross-sectional view illustrating a method for forming a capacitor of a semiconductor memory device in accordance with another embodiment of the invention. The same numeral indicates the same component as compared to the first embodiment.

Referring to FIG. 11, on the result from which the second interlayer dielectric layer (240 in FIG. 5) is removed, the etch stop layer 260 is formed so as to cover the second storage node contact 250. By performing an etch back or CMP process on the etch stop layer, the second storage node contact 250 is exposed. After that, the process of forming the sacrificial layer and the cylindrical storage electrode is performed in the same manner as the first embodiment.

While the invention has been described with respect to the specific embodiments, various changes and modifications may be made without departing from the spirit and scope of the invention as defined in the following claims.

What is claimed is:

1. A method for forming a capacitor of a semiconductor memory device, comprising:
(a) forming a first contact hole having a bottom in a first interlayer dielectric layer formed on a semiconductor substrate;
(b) forming a barrier layer on the bottom of the first contact hole;
(c) forming a first storage node contact filling the first contact hole;
(d) forming a second interlayer dielectric layer on the result of (c) on which the first storage node contact is formed;
(e) forming a second contact hole for exposing a portion of the first storage node contact;
(f) forming a second storage node contact by filling the second contact hole with a conductive layer;
(g) forming a sacrificial layer on the result of (f) in which the second storage node contact is formed;
(h) etching the sacrificial layer to expose the second storage node contact;
(i) forming a cylindrical storage electrode isolated on a unit cell basis on the result of (i) on which the sacrificial layer is etched;
(j) removing the sacrificial layer by a dip out process; and
(k) forming a dielectric layer and a plate electrode to cover the storage electrode.

2. The method of claim 1, wherein forming the barrier layer on the bottom of the first contact hole includes:
depositing a metal layer for silicide on the bottom of the first contact hole; and
forming a metal silicide by heat treating the metal layer for silicide.

3. The method of claim 2, comprising heat treating the metal layer at a temperature of 700 to 900° C. under an atmosphere of nitrogen gas (N₂) for 10 seconds to 300 seconds.

4. The method of claim 2, wherein the metal layer for silicide comprises one of titanium (Ti), tungsten (W), and cobalt (Co).

5. The method of claim 1, comprising forming the first storage node contact of one of titanium nitride (TiN), tantalum nitride (TaN), hafnium nitride (HfN), tungsten (W), ruthenium (Ru), ruthenium oxide (RuO₂), platinum (Pt), iridium (Ir), and iridium oxide (IrO).

6. The method of claim 1, comprising forming the second storage node contact of one of titanium nitride (TiN), tantalum nitride (TaN), hafnium nitride (HfN), tungsten (W), ruthenium (Ru), ruthenium oxide (RuO₂), platinum (Pt), iridium (Ir), and iridium oxide (IrO).

7. The method of claim 1, further comprising, before forming the sacrificial layer, forming an etch stop layer below the sacrificial layer.

8. The method of claim 7, comprising forming the sacrificial layer of an oxide layer and forming the etch stop layer of a nitride layer.

9. The method of claim 1, comprising forming the storage electrode of one of titanium nitride (TiN), tantalum nitride (TaN), hafnium nitride (HfN), ruthenium (Ru), ruthenium oxide (RuO₂), platinum (Pt), iridium (Ir), and iridium oxide (IrO).

10. A method for forming a capacitor of a semiconductor memory device, comprising:
(a) forming a first contact hole in a first interlayer dielectric layer formed on a semiconductor substrate;
(b) forming a first storage node contact by filling the first contact hole with a conductive layer;
(c) forming a second interlayer dielectric layer on the result of (b) formed on the first storage node contact;
(d) forming a second contact hole in the second interlayer dielectric layer to expose a portion of the first storage node contact;
(e) forming a second storage node contact by filling the second contact hole with a conductive layer;
(f) removing the second interlayer dielectric layer;
(g) forming an etch stop layer on the result of (f) from which the second interlayer dielectric layer is removed;
(h) forming a sacrificial layer on the etch stop layer;
(i) patterning the sacrificial layer and the etch stop layer to expose the second storage node contact;
(j) forming a storage electrode isolated on a unit cell basis;
(k) removing the sacrificial layer by a dip out process; and
(l) forming a dielectric layer and a plate electrode covering the storage electrode.

11. The method of claim 10, further comprising forming a barrier layer on a bottom of the first contact hole.

12. The method of claim 11, wherein forming the barrier layer on the bottom of the first contact hole includes:
forming a metal layer for silicide on the bottom of the first contact hole; and
forming a metal silicide by heat treating the metal layer for silicide.

13. The method of claim 12, comprising heat treating the metal layer at a temperature of 700 to 900° C. under an atmosphere of nitrogen gas (N₂) for 10 seconds to 300 seconds.

14. The method of claim 12, wherein the metal layer for silicide comprises one of titanium (Ti), tungsten (W), and cobalt (Co).

15. The method of claim 10, comprising forming the first storage node contact of one of titanium nitride (TiN), tantalum nitride (TaN), hafnium nitride (HfN), tungsten (W), ruthenium (Ru), ruthenium oxide (RuO₂), platinum (Pt), iridium (Ir), and iridium oxide (IrO).

16. The method of claim 10, comprising forming the second storage node contact of one of titanium nitride (TiN), tantalum nitride (TaN), hafnium nitride (HfN), tungsten (W), ruthenium (Ru), ruthenium oxide (RuO₂), platinum (Pt), iridium (Ir), and iridium oxide (IrO).

17. The method of claim 10, further comprising, after forming the etch stop layer, exposing the second storage node contact by conducting an etch back or a chemical mechanical polishing (CMP) process.

18. The method of claim 10, comprising forming the etch stop layer is higher than the height of the second storage node contact so that a portion of the etch stop layer remains between the storage electrodes after patterning the sacrificial layer and the etch stop layer.

19. The method of claim 10, comprising forming the sacrificial layer of an oxide layer and forming the etch stop layer of a nitride layer.

20. The method of claim 10, comprising forming the storage electrode of one of titanium nitride (TIN), tantalum nitride (TaN), hafnium nitride (HfN), ruthenium (Ru), ruthenium oxide (RuO₂), platinum (Pt), iridium (Ir), and iridium oxide (IrO).
